(19) United States
(12) Patent Application Publication
(10) Pub. No.: US 2019/0003743 A1
(43) Pub. Date: Jan. 3, 2019

(54) MRI SYSTEM WITH DUAL COMPRESSORS

(71) Applicant: KONINKLIJKE PHILIPS N.V., EINDHOVEN (NL)

(72) Inventors: GLEN GEORGE PFLEIDERER, LATHAM, NY (US); MATTHEW VOSS, LATHAM, NY (US); JOHN ROBERT ROGERS, LATHAM, NY (US)

(21) Appl. No.: 16/062,712

(22) PCT Filed: Dec. 28, 2016
(86) PCT No.: PCT/EP2016/082782

§ 371 Date: Jun. 15, 2018

Related U.S. Application Data
(60) Provisional application No. 62/272,954, filed on Dec. 30, 2015.

(51) Int. Cl. F25B 9/00; G01R 33/38; F25B 9/14

(52) U.S. Cl. CPC F25B 9/002; G01R 33/3804; H01F 6/04; F25B 2400/075; F25B 9/145

(57) ABSTRACT

An MRI system is provided with a refrigeration system that includes dual compressors that are coupled to a single coldhead that cools the liquid helium in the MRI system. Because the single coldhead receives the compressed refrigerant regardless of the compressor that is being used, the unacceptable cooling loss that would have occurred with redundant coldheads is avoided. By coupling two compressors to a single coldhead, continuous operation can be provided despite a failure of either compressor. The dual refrigeration system may comprise a water-cooled compressor and an air-cooled compressor to enhance MRI system reliability in the event of a failure of the primary compressor or the cooling water circulation system. Alternatively, two water-cooled compressors may be provided, each with its own independent water system. Check valves may be used to enable passive control of the refrigerant gas flow from either compressor to the coldhead, thereby further improving the reliability.

### FIELD OF THE INVENTION

This invention relates to the field of medical systems, and in particular to an MRI system with redundant cooling compressors for reliable operation.

### BACKGROUND OF THE INVENTION

MRI systems use liquid helium to cool the superconducting magnetic coils. Heat is removed from the liquid helium via the use of a refrigeration system comprising a coldhead-compressor combination. Typically, the coldhead extends into the cryostat cooling the liquid helium of the magnet. The refrigeration system also employs helium as a refrigerant which is separate from liquid helium of the magnet. The refrigerant gas is compressed by the compressor, and the coldhead serves as an expansion engine for removing heat. Conventionally, the refrigeration system includes a water circulation system that is coupled to the compressor to dissipate the heat generated by the compression of the helium gas.

The refrigeration system is commonly operated continuously (“24/7”) to prevent the vaporization and subsequent loss of liquid helium. When either the compressor or the water circulation system fails, the expensive liquid helium begins to be lost, and, if not quickly repaired, magnet imaging function will be lost. Therefore, typically, expensive urgent repair service is required.

It is infeasible to provide redundant refrigeration systems due to size and efficiency constraints. A second coldhead would need to be situated in the cryostat reservoir, and would introduce a substantial amount of ambient heat (loss of cooling) into the reservoir when this second refrigeration system is in ‘backup’ (non-operating) mode.

Compounding this problem, advances in technology continue to be developed to reduce the size of the reservoir, thereby reducing the amount of expensive liquid helium required. With a small reservoir, however, the vaporization of a relatively small amount of liquid helium could force a shutdown of the MRI system. Accordingly, the reduction in size of the reservoir causes an increased dependence upon the reliability of the refrigeration system to minimize vaporization of the liquid helium.

### SUMMARY OF THE INVENTION

It would be advantageous to provide an MRI refrigeration system that enables continuous operation of the refrigeration system even in the event of a failure of either the compressor or the cooling water system.

This advantage, and others, may be achieved by providing an MRI system with a refrigeration system that includes dual compressors that are coupled to a single coldhead (expansion engine) that cools the liquid helium in the MRI system. Because the single coldhead receives the helium gas regardless of the compressor that is being used, the unacceptable cooling loss that would have occurred with redundant coldheads is avoided. By coupling two compressors to a single coldhead, continuous operation can be provided for all single-point failures except a failure of the coldhead. Because the coldhead is relatively mechanically ‘passive’, the likelihood of failure of the coldhead is extremely low. The dual refrigeration system may comprise a water-cooled compressor and an air-cooled compressor to provide continued operation in the event of a failure of the water circulation system. Alternatively, two water-cooled compressors may be provided, each with its own independent water system. Check valves may be used to enable passive control of the refrigerant gas flow from either compressor to the coldhead, thereby further improving the reliability.

### BRIEF DESCRIPTION OF THE DRAWINGS

The invention is explained in further detail, and by way of example, with reference to the accompanying drawings wherein:

FIG. 1 illustrates an example MRI system that includes a refrigeration system with dual compressors.

FIG. 2 illustrates an example control system for the example MRI system with dual compressors.

Throughout the drawings, the same reference numerals indicate similar or corresponding features or functions. The drawings are included for illustrative purposes and are not intended to limit the scope of the invention.

### DETAILED DESCRIPTION

In the following description, for purposes of explanation rather than limitation, specific details are set forth such as the particular architecture, interfaces, techniques, etc., in order to provide a thorough understanding of the concepts of the invention. However, it will be apparent to those skilled in the art that the present invention may be practiced in other embodiments, which depart from these specific details. In like manner, the text of this description is directed to the example embodiments as illustrated in the Figures, and is not intended to limit the claimed invention beyond the limits expressly included in the claims. For purposes of simplicity and clarity, detailed descriptions of well-known devices, circuits, and methods are omitted so as not to obscure the description of the present invention with unnecessary detail.

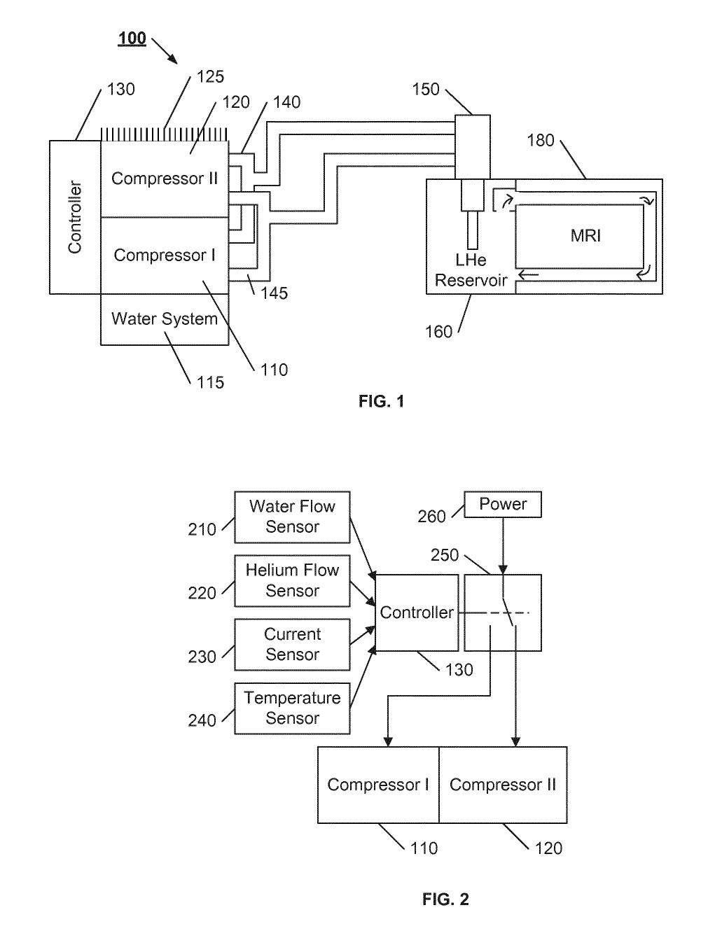

FIG. 1 illustrates an example MRI system 100 that includes dual compressors. Compressor I 110 may be a conventional water-cooled compressor; water system 115 provides the water circulation to cool the compressor. Compressor II 120 may be a conventional air-cooled compressor; heat dissipating fins 125 or other heat dissipating elements may be used to cool the compressor. Typically, at least a portion of the air-cooled compressor II 120 would be exposed to the ambient external environment.

A controller 130 monitors the operation of the system 100 to assure continuous operation. One of the compressors may be identified as the primary compressor, and the other compressor as the backup compressor. The backup compressor may be in an idle mode, or it may be turned off, depending upon the lead time required for the backup compressor to supply the compressed helium gas to the coldhead. If the controller 130 determines that the primary compressor is not operating properly, the controller switches the backup compressor to operating mode, and may switch the primary compressor to an idle state or off, depending upon the nature of the faulty operation.

While the backup compressor is in the operating mode, repairs can be performed on the primary compressor. Because the MRI system 100 is operating properly using the secondary compressor, the urgency of the repair is significantly less than the urgency in a conventional single refrigeration MRI system, and the amount of liquid helium loss is minimized. This decreased urgency will likely reduce the cost of the repair, and may allow sufficient time for a more comprehensive repair than would otherwise be performed. When the primary compressor is repaired, it may be placed in the operating mode and the backup system may be returned to the idle mode. Optionally, the backup compressor may remain in the operating mode and identified as the primary compressor, and the former primary compressor may be placed in idle mode and identified as the backup compressor.

The controller 130 may be configured to enable manual selection of the operating compressor to enable, for example, taking one of the compressors ‘off-line’ for preventive maintenance or periodic inspections. Typically, the primary compressor would be the compressor that is expected to be more efficient or less costly to operate. If the two compressors are of the same type, such as both air-cooled, or both water-cooled, the selection of the operating compressor may be alternated periodically, to balance the wear and tear between the two systems.

Compressor failures can occur due to failure of a variety of internal components. A backup compressor increases system reliability regardless of whether the back up compressor is water or air cooled. If both compressors are water-cooled, each compressor would preferably be coupled to a water system that is independent of the other compressors' water system, to avoid causing a failure of the MRI system 100 due to a failure of the water system.

As noted above, the dual-refrigeration MRI system 100 will provide reliable magnet operation regardless of a failure in the operating compressor or water system. One of skill in the art will recognize that the controller 130 may include redundancies as well, and backup power generation will typically be provided at the medical facilities that the MRI system 100 is likely to be situated. Accordingly, the only single point of failure in the cooling system of the MRI system 100 is the coldhead, which is a relatively mechanically passive element, with very high reliability.

Manifold 140 supplies compressed helium gas from the operating compressor to the MRI equipment, and manifold 145 returns expanded helium gas from the MRI equipment to the operating compressor. The MRI enclosure is typically a cylindrical structure with components mounted concentrically. As illustrated in FIG. 1, the internal components of the MRI system 180, and in particular the superconducting magnetic coils (not illustrated), are cooled by liquid helium. In this manner, heat from the superconducting magnetic coils is transferred back to the reservoir 160 of liquid helium, which is cooled by the coldhead 150. For the purposes of this disclosure, a “reservoir” is herein defined as a volume that contains liquid helium cooled by the coldhead.

The routing of the helium gas from the operating compressor to the coldhead 150 may be actively or passively controlled. In a manifold with active control, the controller 130 controls motors that open or close valves to provide the appropriate flow. In a passive control system, check valves (one-way valves) are used to automatically control the flow of the helium gas to the coldhead. These check valves may be embodied in the output manifold 140 or the return manifold 145. The check valve associated with the currently active compressor is mechanically placed in the ‘open’ state, without external power or influence, due to the flow produced by the active compressor. The check valve associated with the inactive compressor is placed in the ‘closed’ state, without external power or influence, due to the ‘counter-flow’ from the active compressor, and/or the lack of flow produced by the inactive compressor.

FIG. 2 illustrates an example control system for the example MRI system with dual compressors. The controller 130 is configured to receive one or more signals from a variety of sensors, from which the operational status of the operating compressor can be determined. Four example sensors 210, 220, 230, 240 are illustrated in FIG. 2, although one of skill in the art will recognize that other sensors may be used, including redundant sensors.

The water flow sensor 210 monitors the flow of water between the compressor I 110 and the water system 115 (FIG. 1).

The helium flow sensor 220 monitors the flow of helium gas between the operating compressor and the coldhead. This flow may be measured at the output of the manifold 140 or the input of the manifold 145, or elsewhere in the MRI system.

The current sensor 230 monitors the flow of current into the operating compressor (and its water system, if any).

The temperature sensor 240 will typically include multiple temperature sensors to monitor the temperature of the MRI equipment, the compressors, the temperature of the helium at the output and input manifolds 140, 145, the temperature of the water provided by the water system 115, and so on.

The controller 130 receives the signals from the one or more sensors and determines whether each monitored parameter is within a given set of bounds. If the sensors indicate a failure of the operating compressor, the backup compressor is brought into operation. FIG. 2 illustrates the controller 130 coupled to a simple switch 250 that directs power 260 to the selected compressor. One of skill in the art will recognize, however, that a binary on/off selection of one compressor is presented herein for ease of illustration. As noted above, the controller 130 may be configured to place the non-operating compressor in an idle mode that enables a rapid conversion to an operating mode.

The controller 130 may also be configured to monitor the refrigerating system for events other than failures of the operating compressor. The controller 130 may monitor the operation of the non-operating system in an idle mode, and may monitor the operating system for normal operations. If an anomaly is detected, the controller 130 may issue an alert to the operator of the MRI system 100. The operator may take corrective action, such as manually switching the non-operating system to operating mode to enable preventive or corrective maintenance on the prior operating compressor.

While the invention has been illustrated and described in detail in the drawings and foregoing description, such illustration and description are to be considered illustrative or exemplary and not restrictive; the invention is not limited to the disclosed embodiments.

For example, it is possible to operate the invention in an embodiment wherein both compressors 110, 120 are able to be in the operating mode concurrently. This concurrent operation may be provided when additional cooling is required, or it may be provided to enable the backup compressor to fully enter the operating mode before placing the operating unit into the idle mode. One of skill in the art will also recognize that the invention can be embodied without the controller 130, wherein the switching from one compressor to the other is performed manually.

One of skill in the art will also recognize that although this invention is particularly well suited for use with conventional MRI systems that use helium gas to remove heat from the liquid helium that removes heat from the MRI components, other refrigerants may be used.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A refrigeration system for an MRI system comprising:
a first compressor;
a second compressor;
a first manifold that couples an output of the first compressor to an output of the second compressor, and to an input of a coldhead of the MRI system; and
a second manifold that couples an input of the first compressor to an input of the second compressor, and to an output of the coldhead of the MRI system.

2. The refrigeration system of claim 1, including a controller that is configured to detect a failure of the first compressor and to enable operation of the second compressor upon detecting the failure.

3. The refrigeration system of claim 2, wherein the controller detects the failure based on one or more signals from one or more of: a temperature sensor, a current sensor, and a flow sensor.

4. The refrigeration system of claim 1, wherein the first manifold includes a first check valve coupled to the first compressor and a second check valve coupled to the second compressor.

5. The refrigeration system of claim 1, wherein the first and second compressors are water-cooled.

6. The refrigeration system of claim 1, wherein the first compressor is water-cooled and the second compressor is air-cooled.

7. The refrigeration system of claim 1, wherein the first and second compressors are air-cooled.

8. The refrigeration system of claim 1, wherein when the first compressor is in an operating mode, the second compressor is in an idle mode that enables rapid transition to the operating mode.

9. The refrigeration system of claim 1, wherein the first and second compressors use a helium gas refrigerant.

10. The refrigeration system of claim 9, wherein the coldhead serves as an expansion engine that removes heat from a reservoir of liquid helium of the MRI system.

11. An MRI system comprising:
an MRI enclosure that includes:
a reservoir of liquid helium that is circulated to cool components of the MRI enclosure, and
a coldhead that supplies a flow of refrigerant that removes heat from the liquid helium in the reservoir; and
a refrigeration system that includes:
a first compressor;
a second compressor;
a first manifold that couples an output of the first compressor to an output of the second compressor, and to an input of the coldhead of the MRI system; and
a second manifold that couples an input of the first compressor to an input of the second compressor, and to an output of the coldhead of the MRI system.

12. The MRI system of claim 11, including a controller that is configured to detect a failure of the first compressor and to enable operation of the second compressor upon detecting the failure based one or more signals from one or more of: a temperature sensor, a current sensor, and a flow sensor.

13. The MRI system of claim 11, wherein the first manifold includes a first check valve coupled to the first compressor and a second check valve coupled to the second compressor.

14. The MRI system of claim 11, wherein the first compressor is water-cooled and the second compressor is air-cooled.

15. The MRI system of claim 11, wherein when the first compressor is in an operating mode, the second compressor is in an idle mode that enables rapid transition to the operating mode.
